(19) United States
(12) Patent Application Publication
(10) Pub. No.: US 2008/0200000 A1
(43) Pub. Date: Aug. 21, 2008

(54) METHOD FOR MANUFACTURING SEMICONDUCTOR DEVICE

(75) Inventor: Hiroshi MINAKATA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/032,030

(22) Filed: Feb. 15, 2008

(30) Foreign Application Priority Data
Feb. 19, 2007 (JP) 2007-038436

(51) Int. Cl. H01L 21/336

(52) U.S. Cl. 438/303; 257/E21.409

(57) ABSTRACT

After the formation of element isolation insulating films, an n-well, and a p-well on a Si substrate, the Si substrate is subjected to cleaning (step S1) as pretreatment. The surface of the Si substrate is thermally oxidized by rapid thermal oxidation (RTO) to form a silicon oxide film (step S2) as an underlying oxide film. The silicon oxide film is subjected to plasma nitridation (step S3). The plasma nitridation results in the nitridation of the silicon oxide film by the introduction of active nitrogen to form a silicon oxynitride film. Annealing is performed in an ammonia atmosphere (step S4) to further introduce nitrogen into a region near the surface of the silicon oxynitride film. Annealing as post-annealing (step S5) is performed in an atmosphere containing nitrogen and oxygen.

### TECHNICAL FILED

The present invention relates to a method for manufacturing a semiconductor device.

### BACKGROUND

In recent years, progress has been made in increasing the packing density of semiconductor devices. MIS transistors constituting semiconductor devices need to be reduced in size. Thus, a reduction in the thickness of gate insulating films of MIS transistors has been realized. Hitherto, silicon oxide films have been used as gate insulating films. When the thickness of silicon oxide films is reduced, disadvantageously, impurities contained in gate electrodes diffuse easily into channels. Therefore, a technique for using silicon oxynitride films as gate insulating films has been employed.

An example of a method of forming a silicon oxynitride film involves subjecting a silicon oxide film to plasma nitridation or ammonia annealing. In ammonia annealing, many nitrogen atoms are easily present in the vicinity of the interface between the silicon oxynitride film and a channel. These nitrogen atoms may change the mobility and threshold of a transistor. Thus, silicon oxynitride films have been mainly formed by plasma nitridation.

However, subjecting silicon oxide films to plasma nitridation is liable to cause damage near the surfaces of resulting silicon oxynitride films. Thus, the introduction of nitrogen by plasma nitridation in an amount such that the diffusion of impurities contained in gate electrodes can be sufficiently inhibited disadvantageously degrades reliability and increases leakage current.

In the present circumstances, therefore, the amount of nitrogen introduced is suppressed within the allowable range of damage.

### SUMMARY

A method according to the present invention for manufacturing a semiconductor device includes forming an insulating film on a surface of a semiconductor substrate, introducing active nitrogen into the insulating film, and then subjecting the insulating film containing the active nitrogen to heat treatment in a non-oxidative nitrogen-atom-containing gas atmosphere.

### BRIEF DESCRIPTION OF THE DRAWINGS

FIG. 1 is a flow chart showing the outline of a method for producing a semiconductor device according to an embodiment of the present invention;

FIGS. 2A to 2K are a cross-sectional views illustrating a step in a method for producing a semiconductor device according to an embodiment of the present invention;

FIG. 3 is a graph showing measured nitrogen concentration;

FIG. 4 is a graph showing measured flat-band voltage (Vfb);

FIG. 5 is a graph showing measured interface defect density; and

FIG. 6 is a graph showing measured capacitance equivalent thickness (CET).

### DETAILED DESCRIPTION OF THE EMBODIMENTS

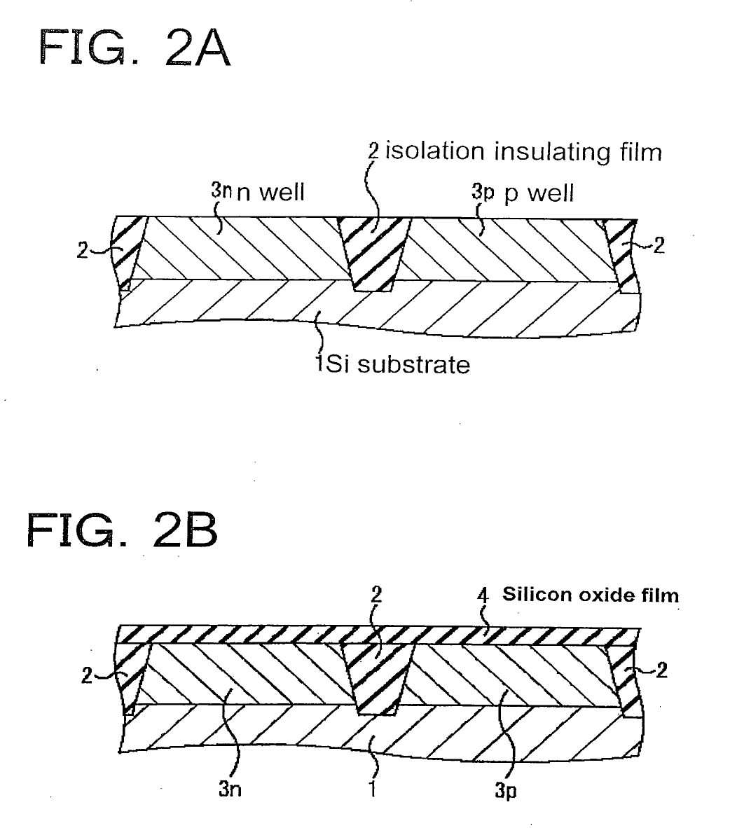

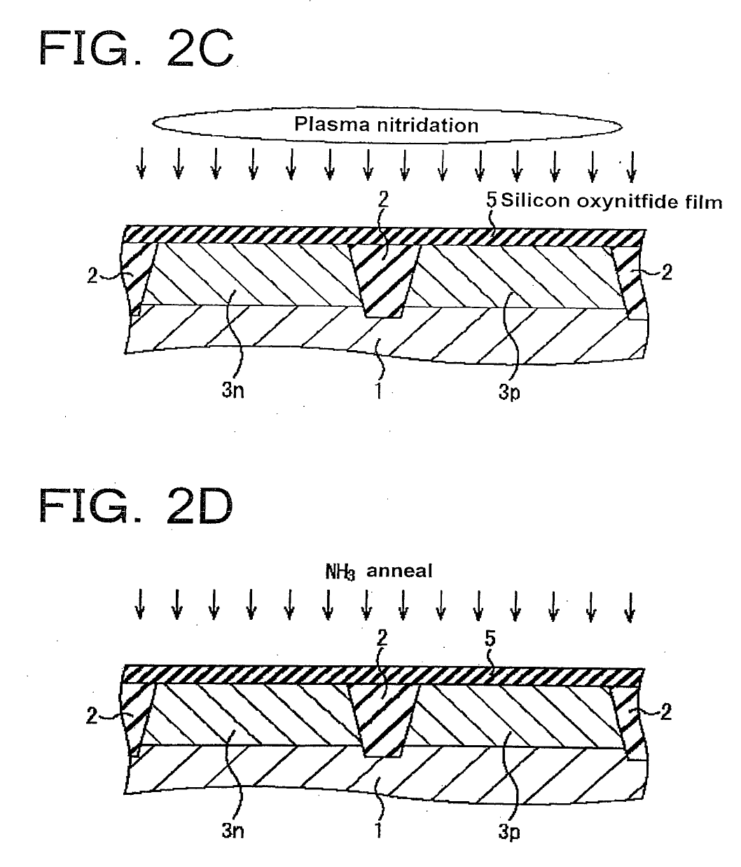

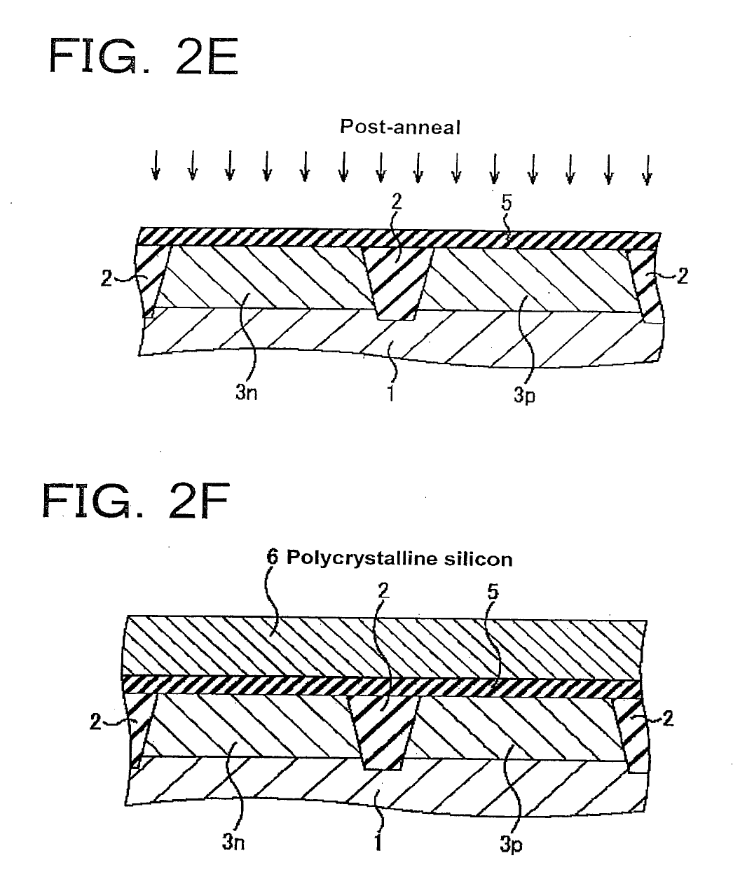

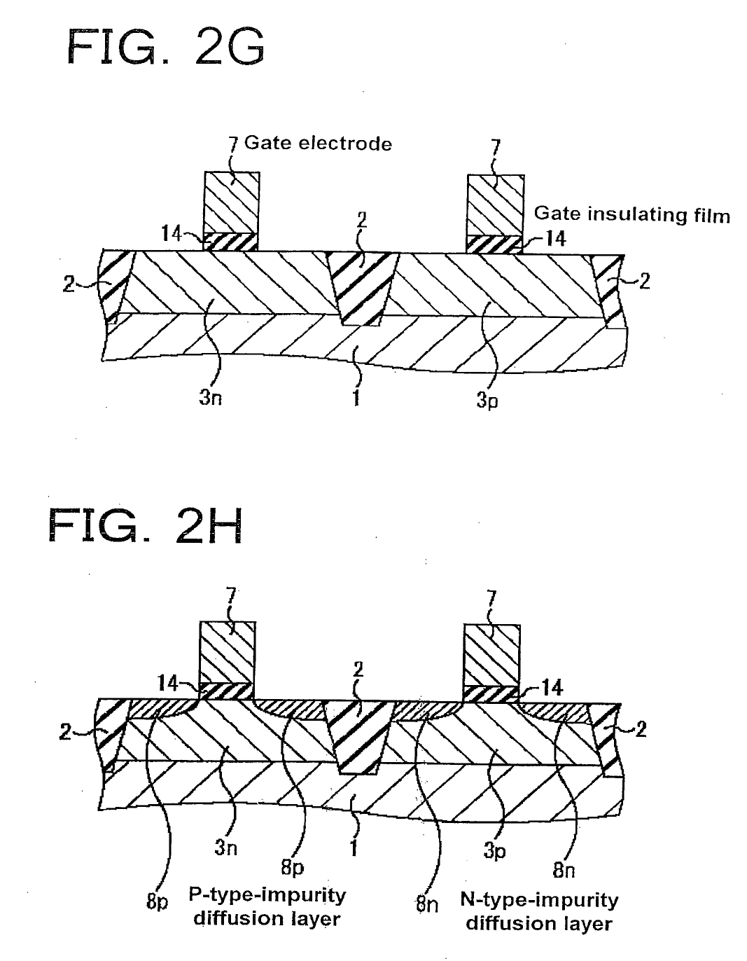

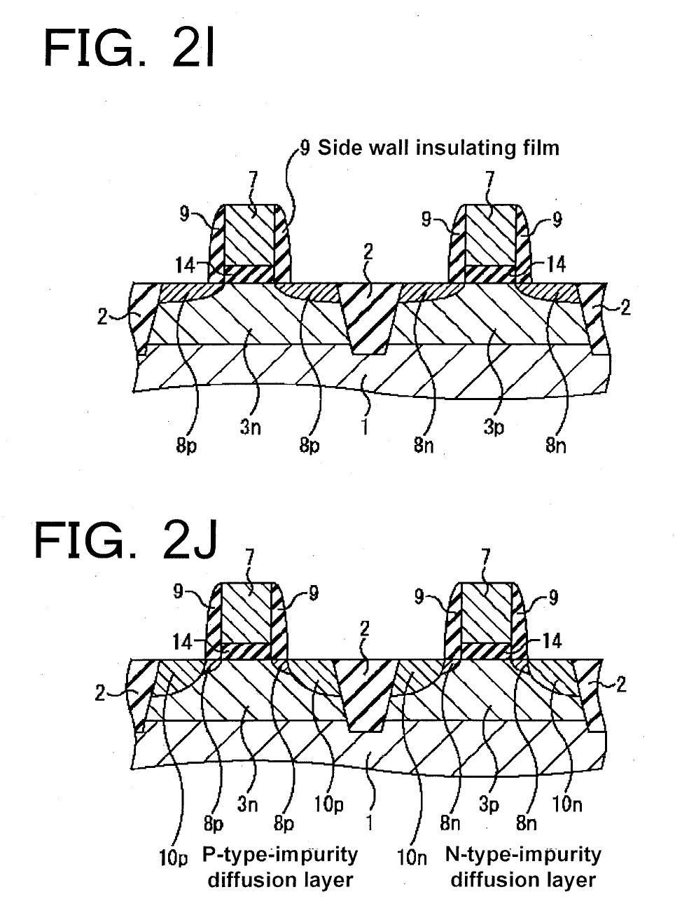

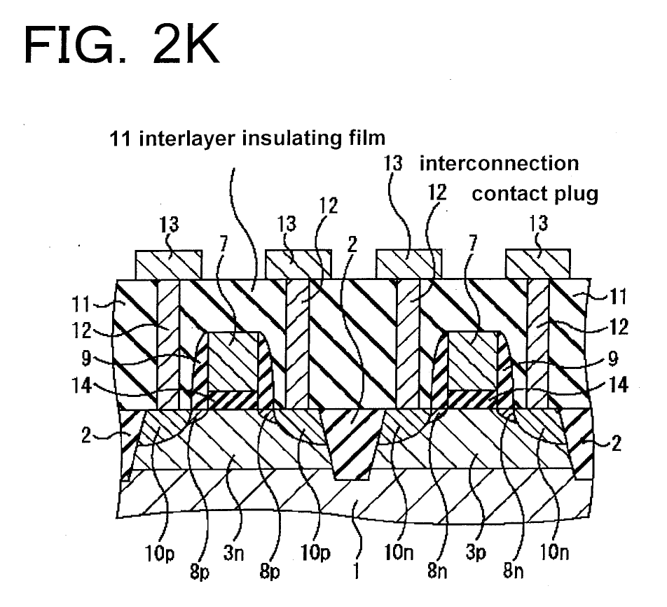

In this embodiment, as shown in FIG. 2A, element isolation insulating films 2 defining element active regions are formed on a surface of a Si substrate 1. The element isolation insulating films 2 are formed by, for example, shallow trench isolation (STI). An n-type impurity is introduced into an element active region to be formed into a p-channel MOS transistor to form an n-well 3n. A p-type impurity is introduced into an element active region to be formed into an n-channel MOS transistor to form a p-well 3p.

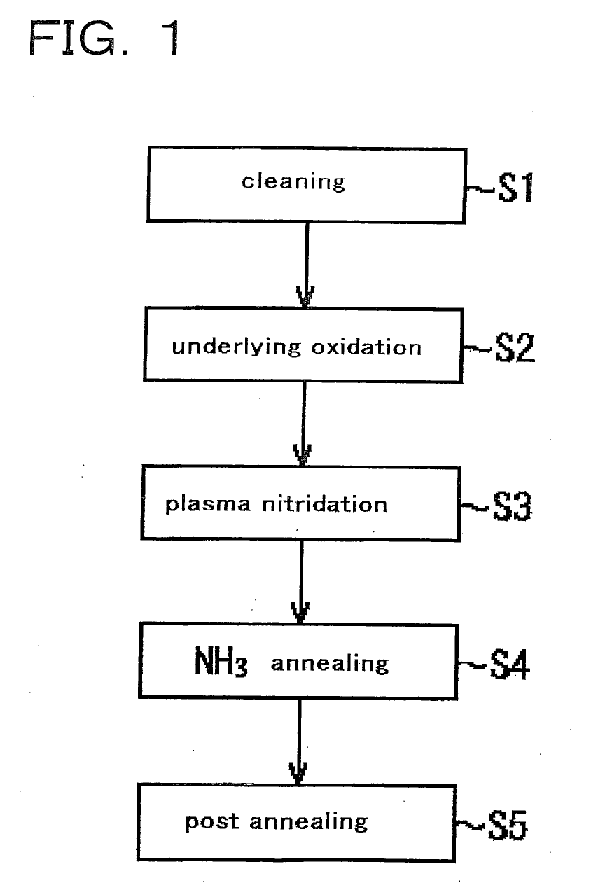

The Si substrate 1 is subjected to cleaning (step S1 as shown in FIG. 1) as pretreatment. An example of cleaning is the RCA cleaning.

As shown in FIG. 2B, the surface of the Si substrate 1 is thermally oxidized by rapid thermal oxidation (RTO) to form a silicon oxide film 4 (step S2 as shown in FIG. 1) as an underlying oxide film. For example, the thermal oxidation is performed in an oxygen atmosphere in a chamber at a temperature of the Si substrate 1 of 900° C. and a pressure of the chamber of 666.6 Pa (5 Torr) for 5 seconds to form the silicon oxide film 4 having a thickness of about 0.9 nm.

The silicon oxide film 4 is subjected to plasma nitridation (step S3 as shown in FIG. 1). As the plasma nitridation, remote plasma nitridation is performed in an atmosphere containing nitrogen or helium in a chamber at a temperature of the Si substrate 1 of 500° C. and at a power of 1,500 W for 30 seconds. As shown in FIG. 2C, the plasma nitridation results in the nitridation of the silicon oxide film 4 by the introduction of active nitrogen to form a silicon oxynitride film 5. In the silicon oxynitride film 5 obtained by plasma nitridation, many nitrogen atoms are present in the vicinity of the surface thereof. The concentration of nitrogen present in the vicinity of the interface between the silicon oxynitride film 5 and the n-well 3n or the silicon oxynitride film 5 and the p-well 3p is low.

As shown in FIG. 2D, annealing is performed in an ammonia atmosphere (step S4 as shown in FIG. 1). For example, the annealing is performed at a temperature of the Si substrate 1 of 800° C. and at a pressure of the chamber of 666.6 Pa (5 Torr) for 5 minutes to further introduce nitrogen into a region near the surface of the silicon oxynitride film 5.

As shown in FIG. 2E, annealing as post-annealing (step S5 as shown in FIG. 1) is performed in an atmosphere containing nitrogen and oxygen. In this annealing, for example, a mixed gas of a nitrogen gas and an oxygen gas, a N₂O gas, a NO gas, or the like is used. For example, the temperature of the Si substrate 1 is set to 850° C. The annealing time is set to 10 seconds. Even when a portion in which Si and N are not sufficiently bonded to each other in the silicon oxynitride film 5 are present, these elements are strongly bonded together by the post-annealing.

As shown in FIG. 2F, a polycrystalline silicon film 6 is formed on the silicon oxynitride film 5 by, for example, chemical vapor deposition (CVD).

As shown in FIG. 2G, the polycrystalline silicon film 6 and the silicon oxynitride film 5 are patterned by lithography and etching to form gate electrodes 7 and gate insulating films 14.

As shown in FIG. 2H, a p-type impurity is introduced into the surface of the n-well 3n with the gate electrode 7 and a resist pattern (not shown) as a mask to form p-type-impurity diffusion layers 8p. An n-type impurity is introduced into the surface of the p-well 3p to form n-type-impurity diffusion layers 8n. Different resist patterns are used for the introduction of the p-type impurity and the introduction of the n-type impurity.

As shown in FIG. 2I, side wall insulating films 9 is formed on side faces of the gate electrodes 7.

As shown in FIG. 2J, a p-type impurity is introduced into the surface of the n-well 3n with the gate electrodes 7, the side wall insulating films 9, and a resist pattern (not shown) as masks to form p-type-impurity diffusion layers 10p.

An n-type impurity is introduced into the surface of the p-well 3p to form n-type-impurity diffusion layers 10n. The amounts of the impurities introduced are larger than those in the case of the formation of the p-type-impurity diffusion layers 8p and the n-type-impurity diffusion layers 8n. Thereby, source and drain regions are formed. Different resist patterns are used for the introduction of the p-type impurity and the introduction of the n-type impurity.

To adjust a threshold voltage, an impurity may be introduced into the gate electrodes 7 during, for example, the formation of the impurity diffusion layers.

As shown in FIG. 2K, an interlayer insulating film 11 is formed on the entire surface. Contact holes communicating with the source and drain regions and the like are formed in the interlayer insulating film 11. Contact plugs 12 are formed in the contact holes. Interconnections 13 in contact with the Contact plugs 12 are formed on the interlayer insulating film 11. Wiring and the like are formed thereon.

Thereby, a semiconductor device including CMOS transistors is completed.

According to this embodiment, in forming the gate insulating films 14, ammonia annealing (step S4) is performed after plasma nitridation (step S3). Thus, although plasma nitridation is not performed to the extent that damage is left, a sufficient amount of nitrogen can be present in the surfaces of the gate insulating films 14. As will hereinafter be described in detail, experiments by the inventors demonstrate that nitrogen does not diffuse in an amount that causes failure to the vicinity of the interfaces between the gate insulating films 14 and the channels (n-well 3n and p-well 3p) by ammonia annealing after plasma nitridation. Thus, according to this embodiment, the gate insulating films 14 having satisfactory characteristics can be obtained attributed to sufficient inhibition of diffusion of impurities from the gate electrodes 7.

Active nitrogen may be introduced by a method other than plasma nitridation. For example, active nitrogen may be generated with a catalyst. Instead of ammonia annealing, for example, nitrogen annealing may be performed as annealing using a non-oxidative nitrogen-atom-containing gas. In view of uniformity and reliability, ammonia annealing may be performed. In annealing using an oxidative gas, the efficiency of nitridation is low. Thus, if nitridation is sufficiently performed, nitrogen may diffuse to the vicinity of the interfaces between the gate insulating films and the channels.

The temperature of the substrate during heat treatment such as ammonia annealing is preferably higher than that during the introduction of active nitrogen, e.g., plasma nitridation. This is because although the temperature of the substrate is preferably low during the introduction of active nitrogen in order to reduce damage, a lower temperature during heat treatment results in difficulty in sufficiently introducing nitrogen.

The temperature of the substrate during post-annealing is preferably higher than that during heat treatment such as ammonia annealing. This is because a lower temperature during post-annealing may result in an insufficient effect.

Experiments actually performed by the inventors and the results will be described below.

In this experiment, according to the above-described embodiment, Sample C was produced by performing the steps up to the post-annealing (step S5). For comparison, Samples A and B were produced. Sample A was produced by forming a silicon oxide film on a Si substrate, subjecting the silicon oxide film to ammonia annealing without plasma nitridation to form a silicon oxynitride film, and performing post-annealing as in Sample C. Sample B was produced by subjecting a silicon oxide film to plasma nitridation to form a silicon oxynitride film and performing post-annealing without ammonia annealing. Samples A and B were produced as in Sample C, except that plasma nitridation or ammonia annealing is omitted.

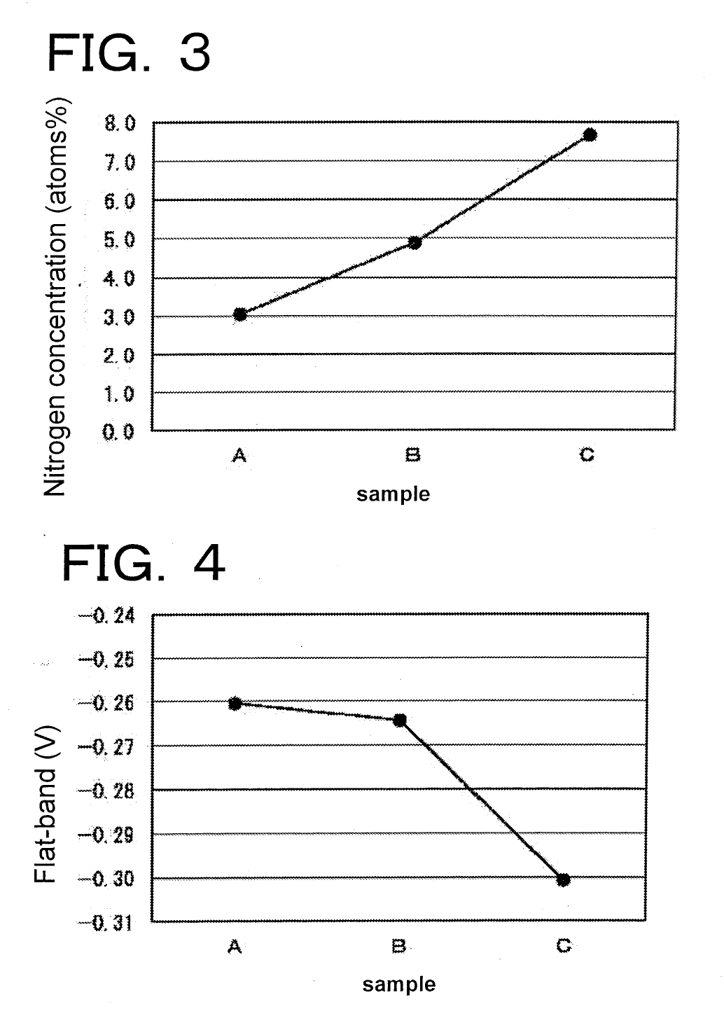

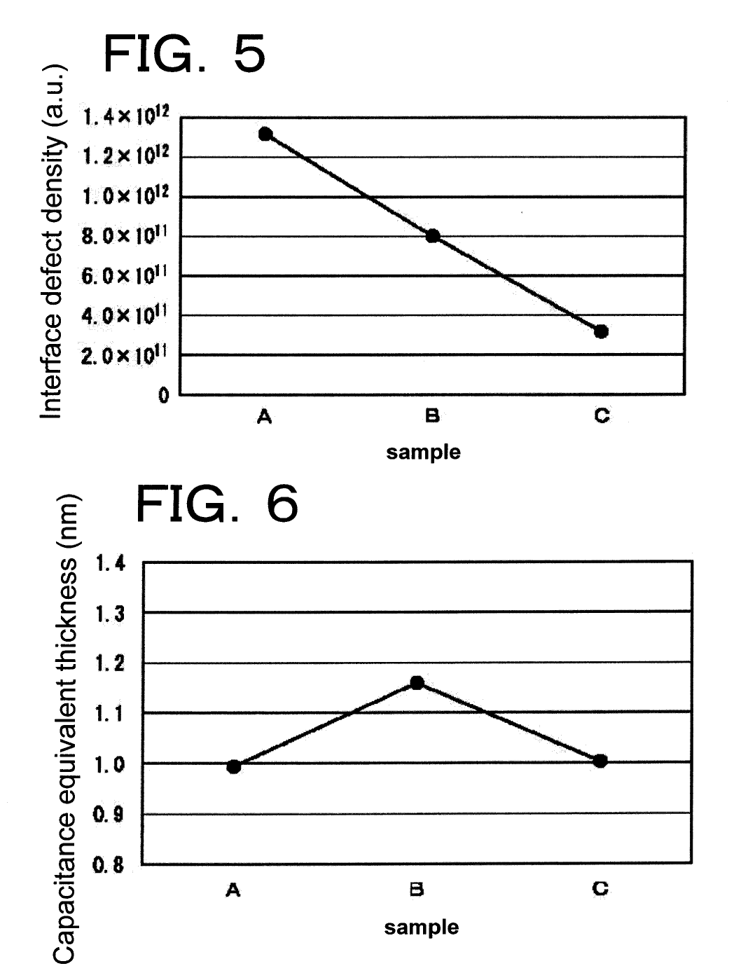

For each sample, the concentration of nitrogen in the silicon oxynitride film, flat-band voltage (Vfb), interface defect density, and capacitance equivalent thickness (CET) were measured. FIG. 3 is a graph showing measured nitrogen concentration. FIG. 4 is a graph showing measured flat-band voltage (Vfb). FIG. 5 is a graph showing measured interface defect density. FIG. 6 is a graph showing measured capacitance equivalent thickness (CET).

As shown in FIG. 3, Sample C had the maximum nitrogen concentration in the entirety of the silicon oxynitride film.

The flat-band voltage reflects the amount of charges present in the vicinity of the interface between the silicon oxynitride film and the channel. Under the conditions of this experiment, there are very few charges at a flat-band voltage of about −0.4 V. As shown in FIG. 4, the flat-band voltage in Sample C was closest to −0.4 V. This means that the least amount of charges present in the vicinity of the interface between the silicon oxynitride film and the channel was observed in Sample C, in other words, the least amount of nitrogen was observed in Sample C.

The interface defect density reflects the defect density in the vicinity of the interface between the silicon oxynitride film and the channel. The defect includes the presence of nitrogen.

As shown in FIG. 5, Sample C had the lowest interface defect density. This means that the least amount of defect density in the vicinity of the interface between the silicon oxynitride film and the channel was observed in Sample C, in other words, the least amount of nitrogen was observed in Sample C.

The capacitance equivalent thickness reflects an effective thickness of the gate insulating film. As shown in FIG. 6, Sample C had a capacitance equivalent thickness comparable to those in Samples A and B. This means that the effective thickness of the gate insulating film of Sample C is not unnecessarily changed.

As described above, in Sample C within the technical range of the present invention, extremely excellent results were obtained compared with Samples A and B according to related art.

The foregoing is considered as illustrative only of the principles of the present invention. Further, since numerous modifications and changes will readily occur to those skilled in the art, it is not desired to limit the invention to the exact construction and application shown and described, and accordingly, all suitable modifications and equivalents may be regarded as falling within the scope of the invention in the appended claims and their equivalents.

What is claimed is:

1. A method for manufacturing a semiconductor device, comprising:
forming an insulating film over a semiconductor substrate;
introducing active nitrogen into the insulating film; and
heating the insulating film containing the active nitrogen in a non-oxidative nitrogen-atom-containing gas atmosphere.

2. The method for manufacturing a semiconductor device according to claim 1, wherein the semiconductor substrate is a silicon substrate.

3. The method for manufacturing a semiconductor device according to claim 2, wherein the insulating film is formed of a silicon oxide film, and is formed by oxidizing a surface of the silicon substrate.

4. The method for manufacturing a semiconductor device according to claim 1, wherein the insulating film containing the active nitrogen is formed by plasma nitridation.

5. The method for manufacturing a semiconductor device according to claim 1, wherein the non-oxidative nitrogen-atom-containing gas is an NH₃ gas.

6. The method for manufacturing a semiconductor device according to claim 1, the method further comprising:
annealing the insulating film in an oxygen-atom-containing gas atmosphere after heating the insulating film in a non-oxidative nitrogen-atom-containing gas atmosphere.

7. The method for manufacturing a semiconductor device according to claim 6, wherein the oxygen-atom-containing gas is at least one selected from the group consisting of an O₂ gas, a N₂O gas, and a NO gas.

8. The method for manufacturing a semiconductor device according to claim 1, wherein a temperature of heating the insulating film containing the active nitrogen is higher than a temperature of introducing of the active nitrogen into the insulating film.

9. The method for manufacturing a semiconductor device according to claim 6, wherein a temperature of annealing the insulating film in the oxygen-atom-containing gas atmosphere is higher than a temperature of heating the insulating film containing the active nitrogen.

10. The method for manufacturing a semiconductor device according to claim 1, wherein the introducing the active nitrogen is performed under conditions such that a surface of the insulating film is not damaged.

11. The method for manufacturing a semiconductor device according to claim 1, wherein the heating the insulating film containing the active nitrogen is performed under conditions such that nitrogen in the insulating film is left on the surface thereof.

12. The method for manufacturing a semiconductor device according to claim 1, the method further comprising:
forming a gate electrode on the insulating film after heating the insulating film containing the active nitrogen.

13. The method for manufacturing a semiconductor device according to claim 12, wherein the gate electrode is composed of polycrystalline silicon containing an impurity.

14. A method for manufacturing a semiconductor substrate, comprising:
forming a gate insulating film on a semiconductor substrate;
forming a gate electrode on the gate insulating film;
forming side wall insulating films on side faces of the gate electrode; and
introducing an impurity into the semiconductor substrate with the side wall insulating films as masks,
wherein the step of forming the gate insulating film comprises:
forming a silicon oxide film;
introducing active nitrogen into the silicon oxide film; and
heating the silicon oxide film containing the active nitrogen film in a nitrogen-atom-containing gas atmosphere.

15. The method for manufacturing a semiconductor device according to claim 14, wherein the silicon oxide film containing the active nitrogen is formed by plasma nitridation.

16. The method for manufacturing a semiconductor device according to claim 14, wherein the nitrogen-atom-containing gas is an NH₃ gas.

17. The method for manufacturing a semiconductor device according to claim 14, the method further comprising a step of:
annealing the silicon oxide film in an oxygen-atom-containing gas atmosphere after heating the insulating film in the nitrogen-atom-containing gas atmosphere.

18. The method for manufacturing a semiconductor device according to claim 17, wherein the oxygen-atom-containing gas is at least one selected from the group consisting of an O₂ gas, a N₂O gas, and a NO gas.

19. The method for manufacturing a semiconductor device according to claim 14, wherein a temperature of heating the silicon oxide film containing the active nitrogen is higher than a temperature of introducing of the active nitrogen into the silicon oxide.

20. The method for manufacturing a semiconductor device according to claim 17, wherein a temperature of annealing the silicon oxide film in the oxygen-atom-containing gas atmosphere is higher than a temperature of heating the silicon oxide film containing the active nitrogen.
